(19) United States
(12) Patent Application Publication
(10) Pub. No.: US 2010/0162066 A1
(43) Pub. Date: Jun. 24, 2010

(54) Acceleration of header and data error checking via simultaneous execution of multi-level protocol algorithms

(76) Inventors: Veera Papirla, Tempe, AZ (US); David A. Daniel, Scottsdale, AZ (US)

Correspondence Address: Law Office of ROBERT C. KLINGER, 2591 Dallas Parkway, Suite 300, FRISCO, TX, 75034, US

(21) Appl. No.: 12/653,829

(22) Filed: Dec. 18, 2009

Related U.S. Application Data
(60) Provisional application No. 61/203,620, filed on Dec. 24, 2008.

(51) Int. Cl. H03M 13/09; G06F 11/10; G06F 11/07

(52) U.S. Cl. 714/746; 714/799; 714/E11.032; 714/E11.023

(57) ABSTRACT

An error detection system and methodology where the undesirable consequence of encapsulation (additional latency or delay) for virtualization applications such as i-PCI or iSCSI is minimized for the vast majority of data transactions. Cyclic Redundancy Checks (CRCs) and checksums are executed simultaneously in parallel, immediately on reception of a data packet regardless of the relative processing order in relation to the OSI model.

### CLAIM OF PRIORITY

This application claims priority of U.S. Provisional Patent Application Ser. No. 61/203,620 entitled “ACCELERATION OF HEADER AND DATA ERROR CHECKING VIA SIMULTANEOUS EXECUTION OF MULTI-LEVEL PROTOCOL ALGORITHMS” filed Dec. 24, 2008, the teachings of which are incorporated herein by reference.

### FIELD OF THE INVENTION

The present invention relates to network communications and virtualization via high speed data networking protocols and specifically to techniques for packet and frame error detection calculation and processing.

### BACKGROUND OF THE INVENTION

In network communications, data transfers are accomplished through passing a transaction from application layer to application layer via a network protocol software stack, ideally structured in accordance with the standard OSI model. A widely used network protocol stack is the Internet Protocol Suite. See FIG. 1 for an illustration of the layered OSI model and the Internet Protocol Suite corresponding protocols.

Virtualization protocols are becoming increasingly widespread, such as iSCSI or i-PCI as described in pending commonly assigned U.S. patent application Ser. No. 12/148,712, the teachings of which are incorporated herein by reference. The data flow encapsulation process involved with virtualization introduces additional latency or delay—an undesirable consequence.

A problem with virtualization protocols is as packets progress through the encapsulation process, the multiple protocol levels of error detection and handling introduce extra delay or latency.

It is highly desirable to find a way to minimize the amount of error function processing time and the associated introduced latency.

### SUMMARY OF THE INVENTION

The invention achieves technical advantages as a system and methodology providing error detection where the undesirable consequence of encapsulation/un-encapsulation (additional latency or delay) associated with virtualization applications, such as i-PCI or iSCSI, is minimized for the vast majority of data transactions. The invention is a solution for the problem of this introduced latency associated with the multiple protocol layers all performing error checks serially as un-encapsulation occurs with received packets/frames.

The invention accomplishes Cyclic Redundancy Checks (CRCs) and checksums simultaneously in parallel, immediately on reception of a data packet regardless of the relative processing order in relation to the OSI model. The net result is a significant reduction in the time required to do error processing, thus reducing the overall latency for data transfers in which no error is found. Since the number of errors seen in a typical modern high-speed network is statistically very low, the end user has a much improved lower-latency experience, which is particularly important for virtualization applications.

### BRIEF DESCRIPTION OF THE DRAWINGS

FIG. 1 depicts the standard layered OSI model and the Internet corresponding protocols;

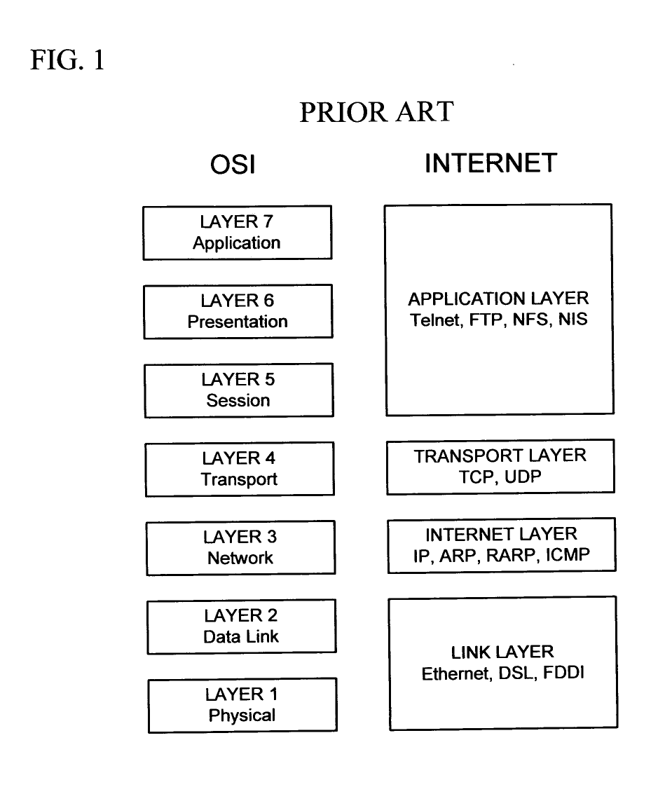

FIG. 2 depicts the data flow for i-PCI involving encapsulation of PCI Express Transaction Layer packets within i-PCI, TCP, IP, and Ethernet headers;

FIG. 3 illustrates error detection for i-PCI;

FIG. 4 depicts the Host Bus Adapter (HBA) major functional Receive (Rx) blocks associated with the invention;

FIG. 5 is an illustration of the invention, showing simultaneous error check logic and flow; and

FIG. 6 is a timing chart that depicts the reduced latency achieved by the invention.

### DETAILED DESCRIPTION OF THE PRESENT INVENTION

One aspect of the invention is an error detection methodology where the undesirable consequence of encapsulation (additional latency or delay) for virtualization applications such as i-PCI or iSCSI is minimized for the vast majority of data transactions. Cyclic Redundancy Checks (CRCs) and checksums are executed simultaneously in parallel, immediately on reception of a data packet regardless of the relative processing order in relation to the OSI model.

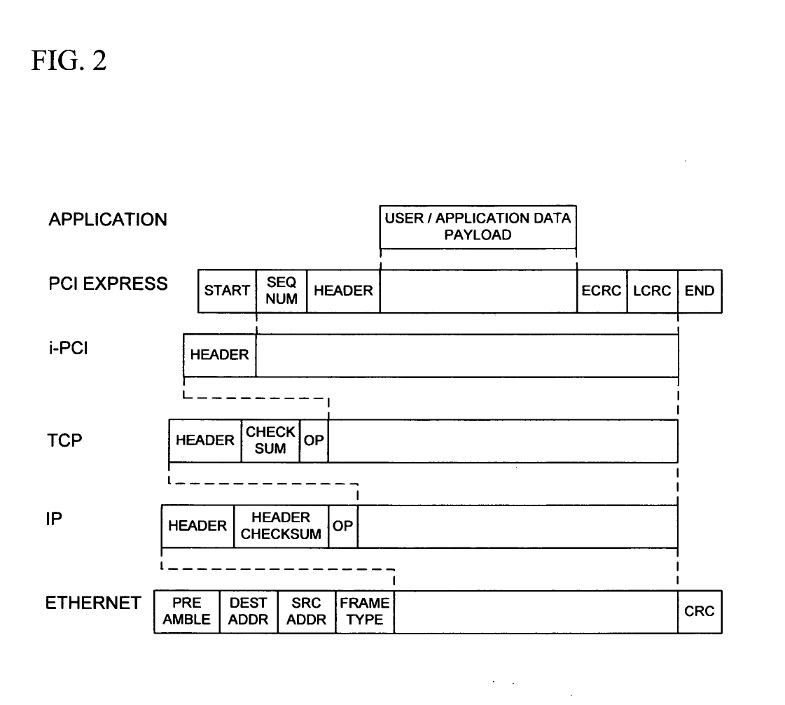

Referring to FIG. 2, data flow for i-PCI involves the encapsulation of PCI Express Transaction Layer packets with the end encapsulation within i-PCI, TCP, IP, and Ethernet headers.

A significant source of the additional latency or delay is attributable to the requirement for robustness of the encapsulation process. In terms of robustness, the goal of i-PCI and similar virtualization protocols is to assure the integrity of user application data transfers to a high degree of certainty. Two key parts of a robust data transfer are 1) Error Detection 2) Error Handling.

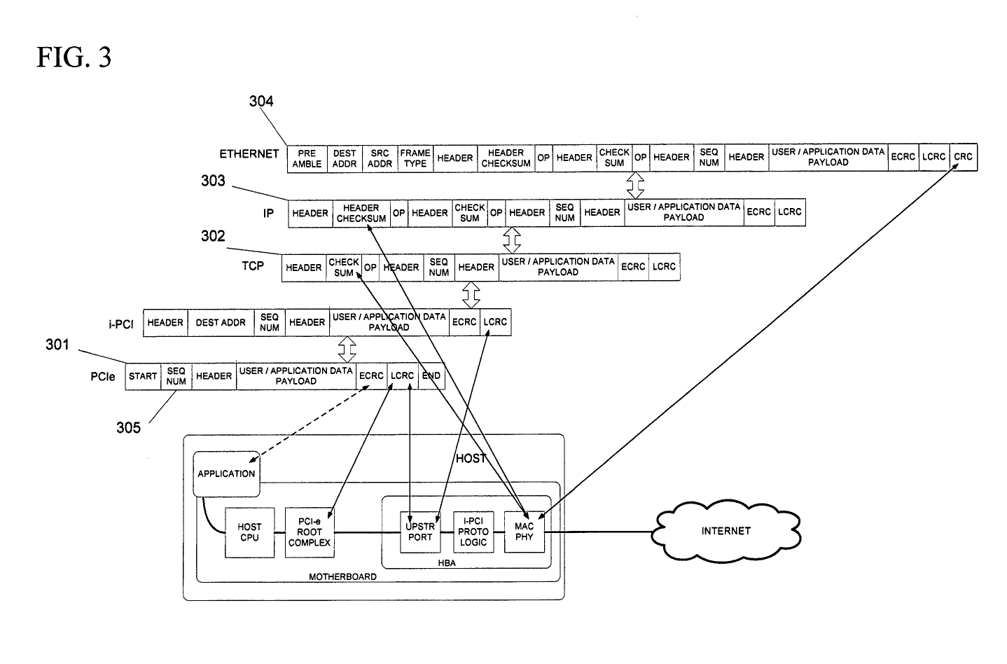

Error Detection: Error detection tends to be computationally intensive, consuming processor cycles and resources, while adding latency. These calculations are typically calculated in sequence as the data is transferred through the OSI layers. FIG. 3 illustrates error detection for i-PCI and involves the following:

PCI Express Error Detection: A PCI Express Transaction Layer Packet (TLP) 301 contains user application data. Data integrity of TLPs is assured via two CRCs. The LCRC is a data link level CRC and is mandatory. The ECRC is a function level CRC and is optional, per the PCI Express Specification.

LCRC: TLPs contain a 32-bit CRC in the last four byte positions. TLP Header and Data are passed down from the transaction layer to the data link layer. The sequence number is added to the packet and the CRC is computed on the TLP per the PCI Express specified algorithm.

ECRC: In addition to the LCRC, TLPs can accommodate an optional 32-bit CRC End-to-End CRC (ECRC) placed in the TLP Digest field at the end of the Data field. The ECRC serves as a function-level end-to-end CRC. The ECRC is calculated by the application or an end device function, per the PCI Express Specification.

TCP Error Detection: TCP provides end-to-end error detection from the original source to the ultimate destination across the Internet. The TCP packet 302 includes a header with a field that contains a 16-bit checksum. The TCP checksum is considered relatively weak in comparison to the 32-bit CRC implemented by PCI Express. Ethernet's 32-bit CRC provides strong data link level assurance, but does not cover the data transfers that happen within switches and routers between the links; TCP's checksum does. The sending device's TCP software on the transmitting end of the connection receives data from an application, calculates the checksum, and places it in the TCP segment checksum field. To compute the checksum, TCP software adds a pseudo header to the segment, adds enough zeros to pad the segment to a multiple of 16 bits, then performs a 16-bit checksum on the whole thing.

IP Error Detection: The IP packet 303 includes a header checksum that just covers the IP header, not the data. The sending device takes data from the TCP layer and passes it down to the IP layer. The IP layer calculates the IP checksum by treating the header as a series of 16-bit integers, adding them together using 1's compliment and then taking the 1's compliment of the result. Since the header includes the source and destination address, the critical routing data integrity is assured.

Ethernet Error Detection: Data integrity of packets associated with i-PCI traffic via an Ethernet data link is assured by the 32-bit CRC computed and placed in the Frame Check Sequence field of an Ethernet frame 304. The sending device takes data passed down from the network layer and forms an Ethernet frame at the data link layer. The 32-bit CRC is calculated and inserted in the Frame Check Sequence field. The packet is then passed down to the physical layer and transmitted.

Error Handling: Error handling covers how the system responds when an error is detected. In virtualization protocols, there are typically several error handling mechanisms implemented at different levels of the OSI model. For i-PCI, error handling is implemented at two levels:

1. The first level is the inherent PCI Express error handling mechanism for TLPs. Each TLP has a sequence number 305 added by the sender at the data link layer. The sender keeps the specific TLP, identified by sequence number, in a retry buffer until it gets an ACK Data Link Layer Packet (DLP) from the receiver at the other end of the link. If an error was detected by the receiver, an NAK DLP is sent and the sender resends the particular TLP from its retry buffer. Additional error checking is done by the end device/receiver, per the “Malformed TLP” mechanism as defined by the PCI Express standard. The receiver is required by the PCI Express protocol to check for discrepancies in the length field, max payload size, TD bit vs. the presence of a digest field, and memory requests that cross 4 k. For further details, refer to the PCI Express protocol.

2. The second level is the inherent TCP error handling mechanism for TCP packets. As the PCI Express packet is encapsulated in a TCP packet, a sequence number is generated as part of the header. The sequence number corresponds to the first byte in the packet, with each subsequent byte in the packet indexed incrementally. The receiver returns an ACK with a sequence number that corresponds to “the-last-byte-it-received-without-error +1” (the next byte it needs from the sender). The sender then transmits (or retransmits) beginning with the last sequence number ACKed.

Modern serial data communications, such as 1 Gbps-10 Gbps Ethernet, are specified for an extremely low frequency of errors. For example, 1 Gbps Ethernet specifies a bit error rate of less than 10⁻¹². A bit error rate of 10⁴ would be considered quite high and justifying further investigation and even possible troubleshooting and/or repair. Thus, in the current state of the art, much processing time and introduced latency is devoted to detecting an error in a very small fraction of the data transfers, thus introducing a significant burden on all transactions.

One aspect of the present invention advantageously takes an opposite approach, whereby the transmission is assumed to be without error, which is statistically far closer to the reality than assuming the transmission is in error. Advantageously, the invention considers error checking a final check, rather than a required set of serialized checks at each layer as the packet progresses up through the protocol stack. With the emphasis on assuming the data is error-free, the time to process the received packets can be greatly reduced.

In one preferred embodiment, the CRC and checksums for all encapsulation layers are executed simultaneously as parallelized functions in hardware logic implemented onboard a Host Bus Adapter (HBA).

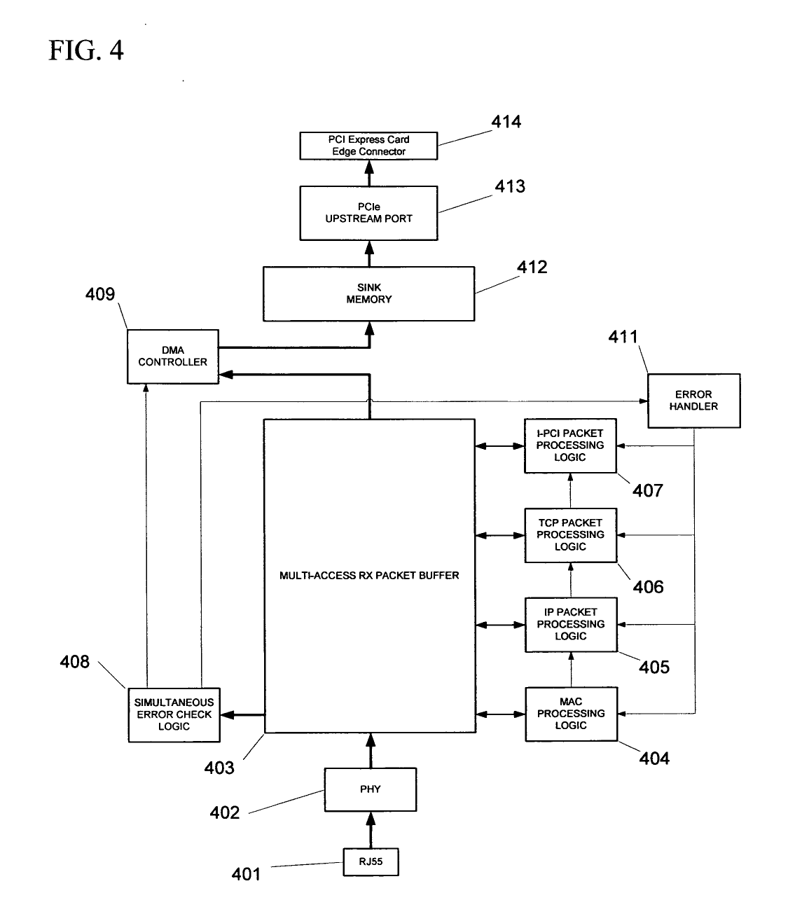

The HBA major functional Receive (Rx) blocks associated with the invention are depicted in FIG. 4. The HBA design includes a PCI Express edge connector 414, a PCI Express Upstream Port 413, Sink Memory 412, DMA controller 409, Error Handler 411, Simultaneous Error Check Logic 408, Multi-access Rx Packet Buffer 403, i-PCI Packet Processing Logic 407, TCP Packet Processing Logic 406, IP Packet Processing Logic 405, Ethernet MAC Processing Logic 404, PHY 402, and connection to the Ethernet 401.

The invention utilizes a non-conventional execution approach, where the received packet is centrally stored in the Multi-Access Buffer 403, such that simultaneous access is enabled. Separate pipelined processing logic “blocks” associated with each level in the protocol stack—MAC Processing Logic 404 for the Ethernet Link Layer, IP Packet Processing Logic 405 for the Internet Layer, TCP 406 and i-PCI 407 Packet Processing Logic for the transport layer, —perform all the operations normally as defined by the protocols, with the exception of the error check and error detection operations. Advantageously, the error check and error detection operations associated with each of the various OSI levels are disassociated from the protocol blocks, and instead, all processed in a separate logic block 408 simultaneously and in parallel beginning immediately upon packet arrival. The logic block referred to as the Simultaneous Error check Logic 408 determines whether all of the error checks are a collective pass or fail and then either enables the DMA to allow the packet to pass to the Sink Memory 412 and Upstream Port 413 or triggers the Error Handler 411.

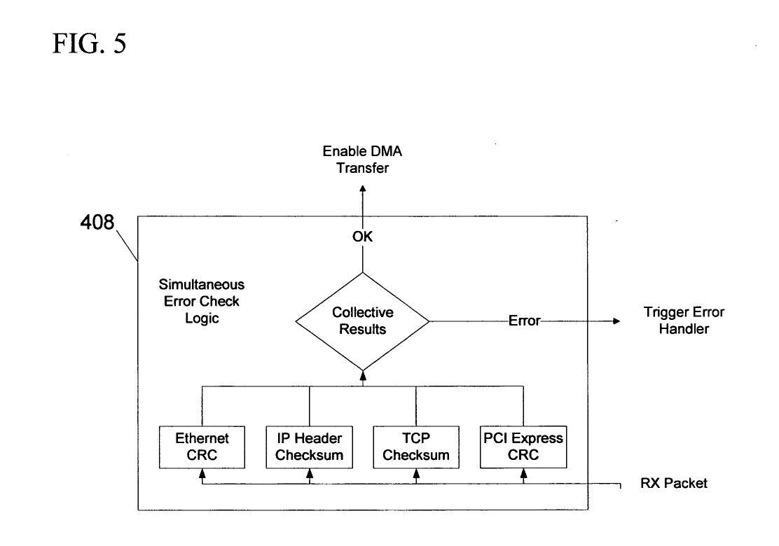

Referring to FIG. 5, calculations are executed immediately and in parallel by the Simultaneous Error Check Logic 408 as soon as the packet arrives, without delaying the higher level protocol error checks. Advantageously, the IP checksum is not dependent on completion of the Ethernet CRC, the TCP checksum is not dependent on completion of the Ethernet CRC or IP checksum, and PCI Express processing is not dependent on completion of the Ethernet CRC, IP checksum, or TCP checksum. Once all the calculations have completed, the collective result is either a pass or fail.

In the case of a pass, the DMA controller 409 is enabled. In the case of a fail, an associated single byte error code, which acts as a trigger, is used to signal the Error Handler 411 to take the appropriate corrective action. The error code byte sent to the Error Handler indicates which protocol failed (i.e. “01h” for an Ethernet CRC failure, “02h” for an IP Header checksum failure, “03h” for a TCP checksum failure . . . ). The Error Handler then signals all of the packet processing logic blocks at and above the failed level. The processing logic blocks that receive the failure signal that are above the failed level then reset to the state they were in prior to receiving the current packet. The processing logic block at the level associated with the failure, then executes the failure response (error handling mechanisms) defined by the particular protocol. The processing logic blocks below the failed level remain unaffected and take no action.

For example and by way of illustration, if the IP checksum fails, the Error Handler 411 receives “02h” from the Simultaneous Error Check Logic 408. The Error Handler then responsively signals the i-PCI Packet Processing Logic 407, TCP Packet Processing Logic 406, and IP Packet Processing Logic 405, since all of these blocks are at or above the failed level. The i-PCI Packet Processing Logic, and the TCP Packet Processing Logic respond by resetting to the state they were in prior to receiving the current packet and the IP Packet Processing Logic executes the response which is defined by the IP protocol, which requires it to simply discard the packet. Although this example illustrates a preferred embodiment for the Error Handler, other actions and responses may be appropriate and enabled.

It is a given for state of the art networks that errors are relatively rare occurrences, thus in the vast majority of data transactions, no errors will be detected and the Error Handler is not triggered. Thus, the data proceeds from the Multi-Access Packet Buffer 403 to the Sink Memory 412 via the DMA controller 409, without further handling, thus minimizing latency and delay. Although there is typically a longer processing time when an error is detected in comparison to a conventional approach, given that errors are relatively rare occurrences for most virtualization applications, the overall impact on the processing time is overwhelming positive with most transactions experiencing much reduced latency.

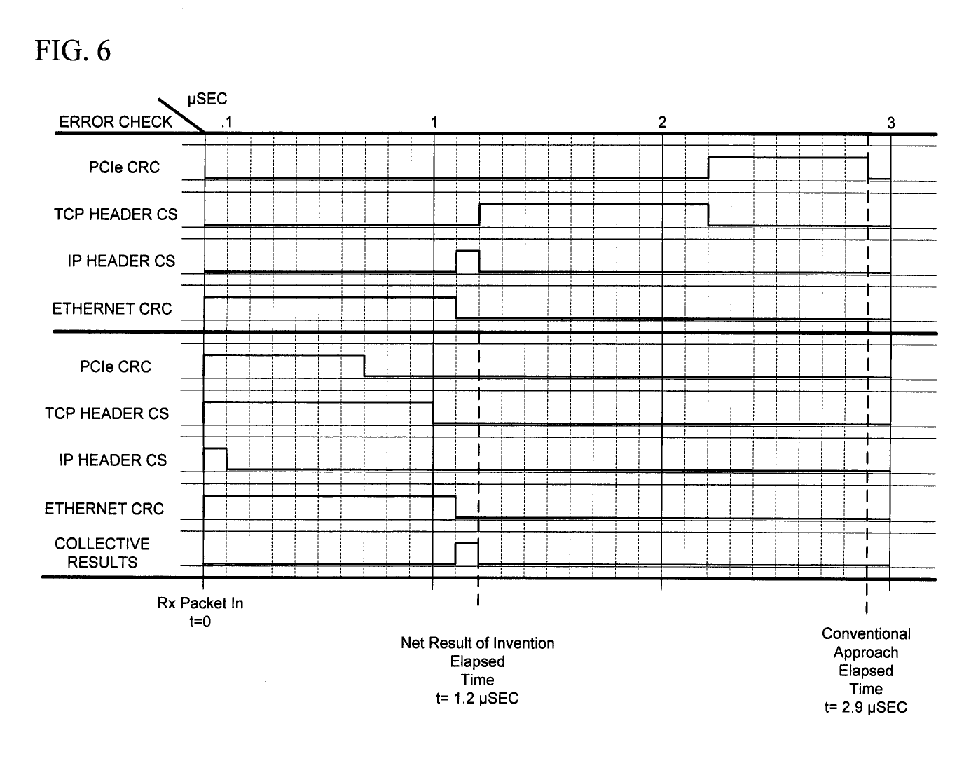

Referring to FIG. 6, the latency improvement may be seen via the timing diagram which shows two scenarios. For purposes of illustration, the diagram assumes all calculations are performed in logic and realized on the HBA in a logic device such as a Field Programmable Gate Array (FPGA) or Application Specific Integrated Circuit (ASIC). The relative latency associated with each of the error calculations are shown as typical for such a device with the logic clocked at a speed of approximately 500 MHz.

In the first scenario, shown in the top half of the diagram, the individual error checks are performed serially as the packet progresses through the protocol stack as is the case with the current state of the art (conventional). In the second scenario, shown in the bottom half of the diagram, the invention is engaged and the individual error checks are performed immediately and simultaneously with a final simple collective result enabling a DMA transfer to sink memory. In comparing the two scenarios, the net result of the invention, when there is no error (the vast majority of data transfers), is a latency improvement of: 2.9-1.2 μsec=1.7 μsec. This equates to a greater than 58% improvement in the delay.

Though the invention has been described with respect to a specific preferred embodiment, many variations and modifications will become apparent to those skilled in the art upon reading the present application. The intention is therefore that the appended claims be interpreted as broadly as possible in view of the prior art to include all such variations and modifications.

What is claimed is:

1. A device, comprising;
a module configured to perform error checking on a data packet processed by a plurality of protocol blocks in a description framework of a computer network protocol, wherein the error checking is configured to be disassociated from the protocol blocks.

2. The module as specified in claim 1 wherein the error checking is configured to be performed regardless of a relative processing order indicated by the description framework of the computer network protocol.

3. The module as specified in claim 2 wherein error checking is configured to be performed immediately on reception of the data packet.

4. The module as specified in claim 1 wherein the error checking comprises Cyclic Redundancy Checks (CRCs) and checksums associated with various abstraction layers of the description framework.

5. The module as specified in claim 4 wherein the CRCs and checksums are configured to be enabled simultaneously in parallel.

6. The module as specified in claim 5 wherein the CRCs and the checksums are configured to be performed regardless of a relative processing order indicated by the description framework of the computer network protocol.

7. The module as specified in claim 5 wherein CRCs and the checksums are configured to be performed immediately on reception of the data packet.

8. The device as specified in claim 1 wherein the computer network protocol is operable with TCP/IP.

9. The device as specified in claim 1 wherein the description framework is configured to enable virtualization of computer resources.

10. The device as specified in claim 9 further comprising a host board adapter including logic incorporating the module.

11. The device as specified in claim 10 where the host board adapter logic includes a multi-access receive packet buffer, error check logic, and an error handler.

12. The device as specified in claim 11 wherein the error checking comprises Cyclic Redundancy Checks (CRCs) and checksums associated with various abstraction layers of the description framework.

13. The device as specified in claim 12 wherein the host board adapter logic is configured to determine whether all of the CRCs and checksums are a collective pass or fail and then either enable a DMA to allow the data packet to pass to a memory and an upstream port, or trigger the error handler.

14. The device as specified in claim 13 wherein the host board adapter logic is configured to send a failure signal indicative of which protocol block failed if there is not a collective pass of the CRCs and checksums.

15. The device as specified in claim 14 wherein the error handler is configured to signal all of the protocol blocks at and above the failed protocol block.

16. The device as specified in claim 15 wherein the device is configured such that the protocol blocks that receive the failure signal that are above the failed protocol block are reset to a state they were in prior to receiving a current said data packet.

17. The device as specified in claim 16 wherein the device is configured such that the processing block at a level associated with the failure is configured to execute a failure response/error handling mechanism defined by the protocol block.

18. The device as specified in claim 17 wherein the device is configured such that the processing blocks below the failed processing block remain unaffected and take no action.

19. The device as specified in claim 1 wherein the module is configured to enable a data transfer path in an extended computer system having a host computer and at least one remote target device.

20. The device as specified in claim 1 wherein the module is configured to encapsulate Ethernet data packets.

21. The mechanism as specified in claim 1 wherein the description framework includes iSCSI.

22. The mechanism as specified in claim 1 wherein the description framework includes PCI Express.
